(19) United States
(12) Patent Application Publication
(10) Pub. No.: US 2011/0204423 A1
(43) Pub. Date: Aug. 25, 2011

(54) SEMICONDUCTOR DEVICE AND MANUFACTURING METHOD THEREOF

(75) Inventor: Mitoko TAMETO, Miyazaki (JP)

(73) Assignee: OKI SEMICONDUCTOR CO., LTD., Tokyo (JP)

(21) Appl. No.: 13/029,837

(22) Filed: Feb. 17, 2011

(30) Foreign Application Priority Data
Feb. 19, 2010 (JP) 2010-035315

(51) Int. Cl. H01L 29/78; H01L 21/336

(52) U.S. Cl. 257/288; 438/296; 257/E21.409; 257/E29.255

(57) ABSTRACT

Disclosed is a semiconductor device that comprises a first semiconductor layer of one conductivity type provided on a substrate; a second semiconductor layer of the one conductivity type provided on the first semiconductor layer and having a lower impurity concentration than the first semiconductor layer; an isolation region extending from one principal face of the second semiconductor layer to reach the substrate; a first region in an element region of the second semiconductor layer isolated by the isolation region and having an opposite conductivity type; a second region of the one conductivity type provided in the element region extending from the one principal face to reach the first semiconductor layer and having an impurity concentration higher than the second semiconductor layer; and an insulation region extending from the one principal face to the first semiconductor layer, kept away from the substrate, and provided between the first and the second regions.

### CROSS-REFERENCE TO RELATED APPLICATION

This application claims priority under 35 USC 119 from Japanese Patent Application No. 2010-035315 filed on Feb. 19, 2010, the disclosure of which is incorporated by reference herein.

### BACKGROUND

1. Field of the Invention

The present invention relates to a semiconductor device and a manufacturing method thereof, and more particularly to a high withstand voltage MOS transistor device and a manufacturing method thereof.

2. Related Art

Some of high withstand voltage MOS transistor devices have a structure in which an epitaxial layer is provided on an embedded layer laid on a substrate, a high withstand voltage MOS transistor element is provided in the epitaxial layer, and a diffusion layer is provided which supplies an electric potential from the surface of the epitaxial layer to the embedded layer (refer to Japanese Patent Application Laid-Open (JP-A) No. 2002-190591).

A conventional high withstand voltage MOS transistor having the above-described structure is explained below with reference to FIG. 4.

An N-type embedded layer 13 is provided on a p-type silicon substrate 11, and an n⁻-type epitaxial layer 15 is provided on the n-type embedded layer 13. Field oxide films 21, 23, 25 are provided at one principal face 10 of the n⁻-type epitaxial layer 15. A high withstand voltage MOS transistor 75 is provided at the one principal face 10 of the n⁻-type epitaxial layer 15 of an element region 71 isolated by an isolation trench 50. An n-type sinker 17 that supplies an electric potential to the n-type embedded layer 13 is provided in such a manner as to extend from the one principal face 10 of the n⁻-type epitaxial layer 15, which is exposed in an opening 24 between the field oxide films 23, 25 within the element region 71, to the n-type embedded layer 13. An n⁺-type contact area 19 is provided at the one principal face 10 of the n⁻-type epitaxial layer 15, which is exposed in the opening 24. A p⁺-type drain contact area 37 that is to come into contact with the a p⁻ drain region 35 of the high withstand voltage MOS transistor 75 is provided on a part of the p⁻ drain region 35, which is exposed in an opening 22 between the field oxide films 21, 23.

In the high withstand voltage MOS transistor having the above-described structure, a high voltage is applied to the drain, and therefore, when a depletion layer that extends from the drain region 35 having a relatively high concentration and the n-type sinker 17 having a relatively high concentration come into contact with each other, an electric field concentrates at a place where the areas of high concentration come into contact with each other, and element breakage would be caused starting from the place, thereby leading to deterioration of withstand voltage.

In order to deal with the above-described problem, conventionally, the drain region 35 and the n-type sinker 17, which greatly differ from each other in electric potential, are separated from each other to relax electric field. However, in this practice, the element region increases, which runs counter to the technical field of the tendency that the element region decreases. The distance between the drain region 35 and the n-type sinker 17 does not adversely affect the element performance of the MOS transistor, and therefore, it is desired that the diatance is made to as small as possible insofar as withstand voltage of the element is not affected.

### SUMMARY

A main object of the present invention is to provide a semiconductor device in which an element region is small and withstand voltage of the element is high, and a manufacturing method thereof.

According to a first aspect of the present invention, there is provided a semiconductor device comprising:

a first semiconductor layer of one conductivity type provided on a substrate;

a second semiconductor layer of the one conductivity type provided on the first semiconductor layer, the second semiconductor layer having a lower impurity concentration than the first semiconductor layer;

an isolation region that extends from one principal face of the second semiconductor layer to reach the substrate, the one principal face being located at a side opposite to the first semiconductor layer;

a first region provided in an element region of the second semiconductor layer isolated by the isolation region, the first region having an opposite conductivity type to the one conductivity type;

a second region of the one conductivity type provided in the element region, the second region extending from the one principal face to reach the first semiconductor layer, and having an impurity concentration higher than that of the second semiconductor layer; and

an insulation region provided between the first region and the second region, the insulation region extending from the one principal face of the second semiconductor layer to the first semiconductor layer and being kept away from the substrate.

According to a second aspect of the present invention, there is provided a manufacturing method of a semiconductor device, comprising:

preparing a semiconductor substrate that has a substrate, a first semiconductor layer of one conductivity type that is provided on the substrate, and a second semiconductor layer of the one conductivity type that is provided on the first semiconductor layer, the first semiconductor layer having an impurity concentration higher than that of the second semiconductor layer;

forming a first region by implanting first impurities of an opposite conductivity type to the one conductivity type into a surface of the semiconductor substrate from a side of the second semiconductor layer;

forming a second region extending from the surface of the semiconductor substrate to reach the first semiconductor layer by implanting second impurities of the one conductivity type into the surface from the side of the second semiconductor layer, the second region having an impurity concentration higher than that of the second semiconductor layer;

forming a first trench that surrounds the first region and the second region, and extends from the surface of the semiconductor substrate to reach the substrate;

forming a second trench between the first region and the second region, the second trench extending from the surface of the semiconductor substrate to reach the first semiconductor layer;

forming a first insulator in the first trench; and

forming a second insulator in the second trench.

### BRIEF DESCRIPTION OF THE DRAWINGS

An exemplary embodiment of the present invention will be described in detail based on the following figures, wherein:

FIG. 1 is a schematically longitudinal sectional view for explaining a semiconductor device according to a preferred embodiment of the present invention.

FIG. 2 is a diagram for explaining a relationship between a trench opening and a trench depth.

FIG. 3 is a graph for explaining a relationship between a trench opening and a trench depth.

FIG. 4 is a schematically longitudinal sectional view for explaining a conventional semiconductor device.

### DETAILED DESCRIPTION

A preferred embodiment of the present invention will be described hereinafter with reference to the attached drawings.

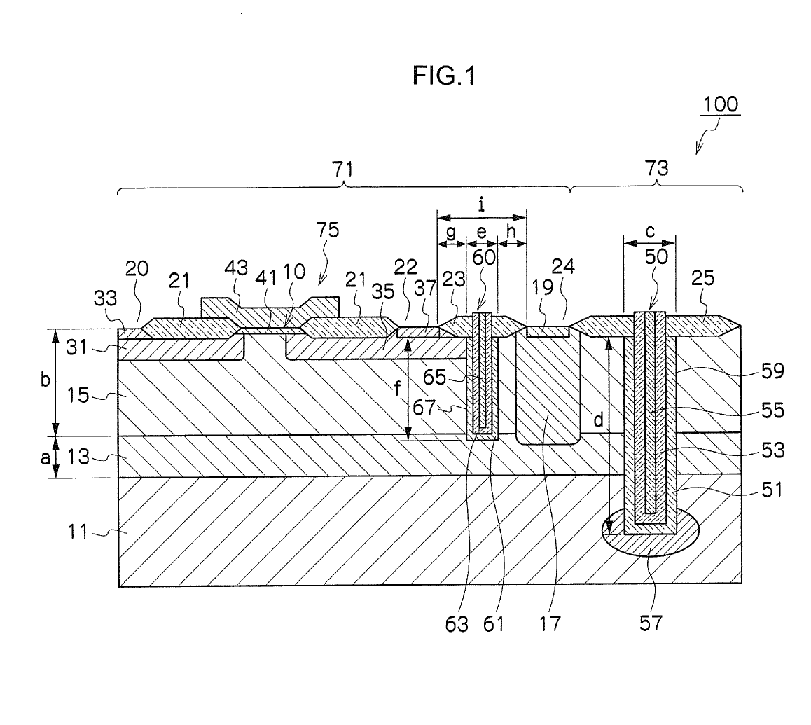

Referring to FIG. 1, in a preferred semiconductor device 100 of the present invention, an n-type embedded layer (NBL) 13 is provided on a p-type silicon substrate 11, and an n⁻-type epitaxial layer 15 is provided on the n-type embedded layer 13. The n⁻-type epitaxial layer 15 has a low impurity concentration compared to the n-type embedded layer 13. Field oxide films 21, 23 and 25 are provided on one principal face of the n⁻-type epitaxial layer 15.

An isolation trench 50 is provided below the field oxide film 25. The isolation trench 50 is provided so as to extend from the one principal face 10 of the n⁻-type epitaxial layer 15 into the p-type silicon substrate 11. A channel stopper 57 is formed around the bottom portion of the isolation trench 50 in the p-type silicon substrate 11. The isolation trench 50 includes an insulator comprised of a trench 59 that extends from the one principal surface 10 of the n⁻-type epitaxial layer 15 into the p-type silicon substrate 11, a thermally oxidized film 51 provided within the trench 59, an LP-TEOS (Low Pressure TEOS; TEOS is an abbreviated name of Si(OC₂H₅)₄) oxide film 53, and an LP-TEOS oxide film 55. An isolation area 73 is formed by the field oxide film 25 and the isolation trench 50.

A high withstand voltage MOS transistor 75 is provided on the one principal face 10 of the n⁻-type epitaxial layer 15 of the element region 71, which is isolated by the isolation trench 50. The high withstand voltage MOS transistor 75 includes a gate electrode 43 that is provided on the one principal face 10 of the n⁻-type epitaxial layer 15 via a gate insulating film 41, and a p⁻ source region 31 and a p⁻ drain region 35, which are provided at the both sides of the gate electrode 43. The p⁺-type drain contact area 37 that is to come into contact with the p⁻ drain region 35 is provided on the p⁻ drain region 35 that is exposed at the opening 22 between the field oxide films 21 and 23. A p⁺-type source contact area 33 that is to come into contact with the p⁻ source region 31 is provided on the p⁻ source region 31 that is exposed at the opening 20 between the field oxide films 21.

An n-type sinker (n-type body) 17 that supplies an electric potential to the n-type embedded layer 13 is provided so as to extend from the one principal face 10 of the n⁻-type epitaxial layer 15 that is exposed at the opening 24 between the field oxide films 23, 35 in the element region 71 to reach the n-type embedded layer 13. An n⁺-type contact area 19 is provided on the one principal face 10 of the n⁻-type epitaxial layer 15 that is exposed at the opening 24. A bottom portion of the n-type sinker 17 does not reach the p-type silicon substrate 11. The impurity concentration of the n-type sinker 17 is higher than that of the n⁻-type epitaxial layer 15. The n-type embedded layer 13 is provided so as to electrically insulate the n⁻-type epitaxial layer 15 from the p-type silicon substrate 11. The n-type sinker 17 is provided so as to prevent the n-type embedded layer 13 from being brought into a floating state, thereby preventing electric properties of the high withstand voltage MOS transistor 74 from being adversely affected.

An insulation trench 60 is provided between the p⁻ drain region 35 of the high withstand voltage MOS transistor 75, and the n-type sinker 17 in such a manner as to extend from the one principal face 10 of the n⁻-type epitaxial layer 15 to reach the n-type embedded layer 13. The insulation trench 60 does not reach an interface between the n-type embedded layer 13 and the p-type silicon substrate 11. The insulation trench 60 is provided below the field oxide film 23. The isolation trench 60 includes an insulator comprised of a trench 67 that extends from the one principal face 10 of the n⁻-type epitaxial layer 15 to the n-type embedded layer 13, a thermally oxidized film 61 provided in the trench 67, an LP-TEOS oxide film 63 and an LP-TEOS oxide film 65.

In the present embodiment, the isolation trench 60 is provided between the p⁻ drain region 35 of the high withstand voltage MOS transistor 75, and the n-type sinker 17 in such a manner as to extend from the one principal face of the n⁻-type epitaxial layer 15 to reach the n-type embedded layer 13. Due to the above-described structure, electric insulation between the p⁻ drain region 35 and the n-type sinker 17 is realized. Further, a depletion layer that extends from the p⁻ drain region 35 does not extend to the n-type sinker 17, and therefore, compared to a conventional system in which electrical interference is suppressed by gaining a distance between the p⁻ drain region 35 and the n-type sinker 17, an increase in the element size may be restrained.

In the present embodiment, the isolation trench 60 does not electrically isolate adjacent elements like a conventional trench used for element isolation, but is formed in consideration of electrical interference in the same element region. The lower end of the insulation trench 60 is disposed in the n-type embedded layer 13, and does not reach the lower surface of the n-type embedded layer 13. Therefore, even in a case in which the insulation trench 60 is formed, the n-type sinker 17 can provide electric potential to the n-type embedded layer 13 below the high withstand voltage MOS transistor 75. The lower end of the insulation trench 60 preferably comes into contact with the upper face of the n-type embedded layer 13. If doing so, it is possible to gain an electrical path between the n-type sinker 17 and the n-type embedded layer 13 below the high withstand voltage MOS transistor 75 to the maximum. In this manner, the depth of the insulation trench 60 is determined in consideration of the n-type embedded layer 13. The above-described structure is apparently different from a trench used for isolation of elements, which extends beyond the n-type embedded layer 13 to reach the p-type silicon substrate 11.

Next, a manufacturing method of a semiconductor device 100 according to the present embodiment is described.

A trench process of forming trenches allows formation of trenches having different depths at the same time, by varying the widths of the trenches without using an additional mask and an additional process. In the present embodiment, using the findings, the isolation trench 60 is formed by forming a trench whose depth is shallower than the isolation trench 50 between the p⁻ drain region 35 of the high withstand voltage MOS transistor 75, and the n-type sinker 17.

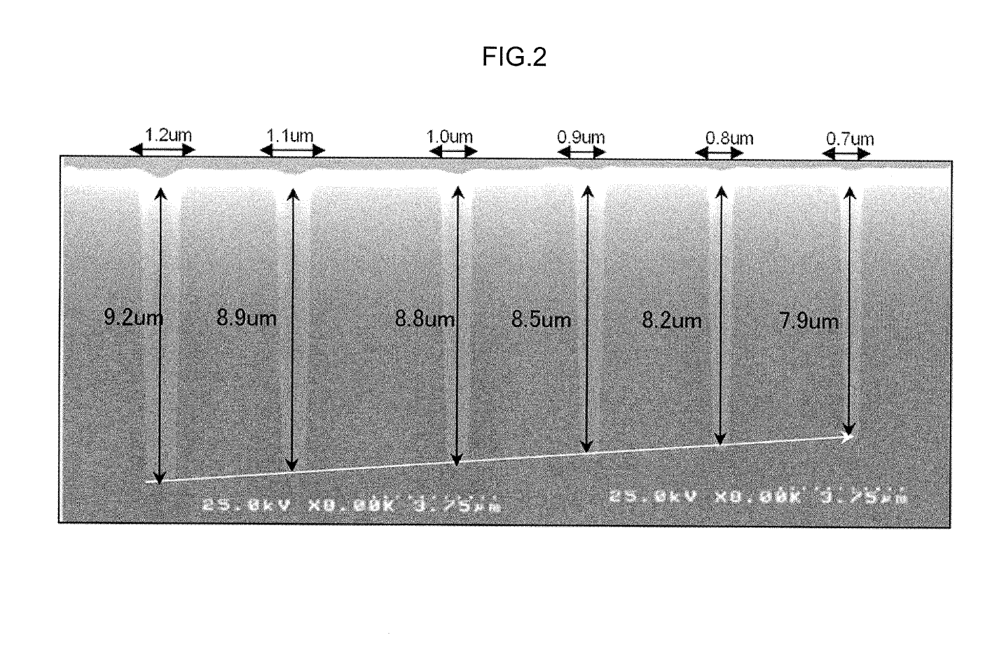

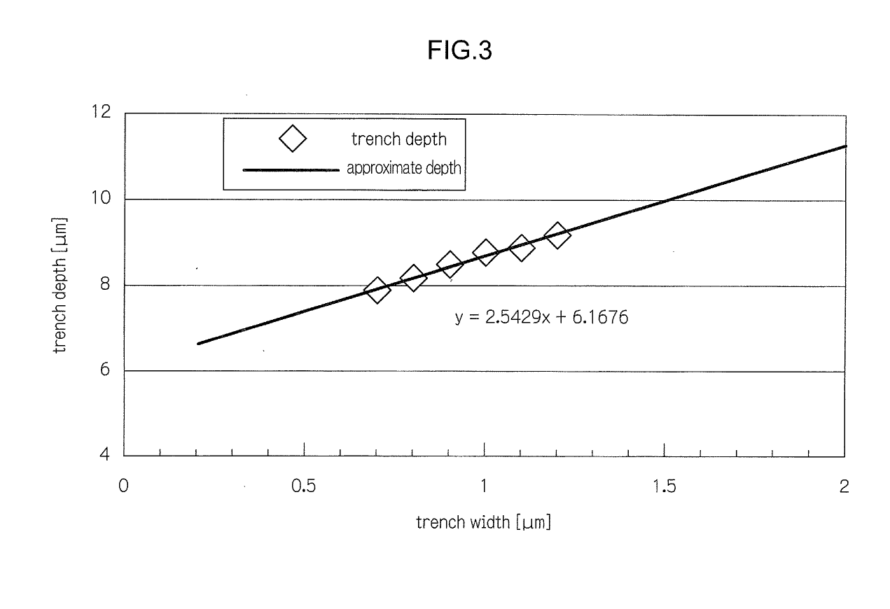

As shown in FIG. 2 and FIG. 3, a depth of the trench depends on an opening width of the trench. Therefore, by changing the opening widths of the trenches, trench structures having different depths can be formed at the same time without using an additional mask and an additional process. In the present embodiment, utilizing the findings, in the structure in which the n-type embedded layer 13 having a thickness “a” (=2 μm) is provided on the p-type silicon substrate 11, and the n⁻-type epitaxial layer 15 having a thickness “b” (=7 μm) is provided on the n-type embedded layer 13, for example, as shown in FIG. 1, a trench 59 having a trench opening width “c” (=1.8 μm), and a trench 67 having a trench opening width “e” (=0.4 μm), which is narrower than the trench 59, are formed at the same time. The trench 59 having a trench opening width “c” (=1.8 μm) becomes a trench having a depth “d” (=10.8 μm) and reaching the p-type silicon substrate 11, and the trench 67 having a trench opening width “e” (=0.4 μm) becomes a trench whose bottom isolates the surface connected by the n-type embedded layer 13 at the depth “f” (=7.18 μm). The shallow trench 67 is formed between the p⁻ drain region 35 of the high withstand voltage p-type MOS transistor 75 and the n-type sinker 17, and thereafter, the trench is embedded with an insulator to form the insulation trench 60.

Next, a manufacturing method of a semiconductor device 100 according to the present embodiment is described in order of processes.

First, the n-type embedded layer 13 of 1×10¹⁸ cm⁻³ is formed on the p-type silicon substrate 11. Then, an n⁻-type silicon (Si) semiconductor is epitaxially grown to form the n⁻-type epitaxial layer 15. Subsequently, in order to provide the n-type embedded layer 13 with an electric potential, the sinker (DN) 17 that connects the n-type embedded layer 13 and the one principal face 10 is formed by photolithography and ion implantation techniques. Then, the field oxide films 21, 23 and 25 are formed by a well-known LOCOS technique.

Thereafter, the insulation trench 60 and the isolation trench 50 are formed. The forming method is described below. The thickness “a” of the n-type embedded layer 13 is 2.0 μm, and the thickness “b” of the n⁻-type epitaxial layer 15 is 7.0 μm.

First, the field oxide film 25 of the isolation region 73 used for the element isolation, and a silicon (Si) portion (including the n⁻-type epitaxial layer 15, the n-type embedded layer 13, and the p-type silicon substrate 11) therebelow are etched, and the field oxide film 23 of the element region 71 and a silicon portion (including the n⁻-type epitaxial layer 15, the n-type embedded layer 13, and the p-type silicon substrate 11) therebelow are etched, whereby the trench 59 and the trench 67 are formed at the same time. In this case, the opening width “c” of the trench 59 is 1.8 μm and the depth “d” thereof is 10.8 μm, while the opening width “e” of the trench 67 is 0.4 μm and the depth “f” thereof is 7.18 μm.

Thereafter, a thermally oxidized film 51 is formed by thermal oxidation on an inner wall of the trench 59, and a thermally oxidized film 61 is formed by thermal oxidation on an inner wall of the trench 67.

Then, 3×10¹³/cc of boron is implanted in the bottom portion of the trench 59 for preventing leakage, whereby a channel stopper 57 is formed.

Then, the inner portions of the trenches 59, 67 are each embedded with an oxide film, and therefore, the LP-TEOS oxide films 53, 63 are formed at the same time, and thereafter, annealing is performed at 1000° C. in the atmosphere of nitrogen.

Then, the LP-TEOS oxide films 55, 65 are further formed at the same time, and annealing is performed again at 1000° C. in the atmosphere of nitrogen.

Then, a BPSG (Boron Phosphorus Silicon Glass) film is formed and the surface thereof is planarized, and thereafter, an etch back treatment of the oxide film is performed, whereby the insulation trench 60 and the isolation trench 50 are formed.

Then, a transistor or the like (in this case, a high withstand voltage p-type MOS transistor 75) is formed in the element region 71 at the inner side of the isolation trench formed in the above-described manner.

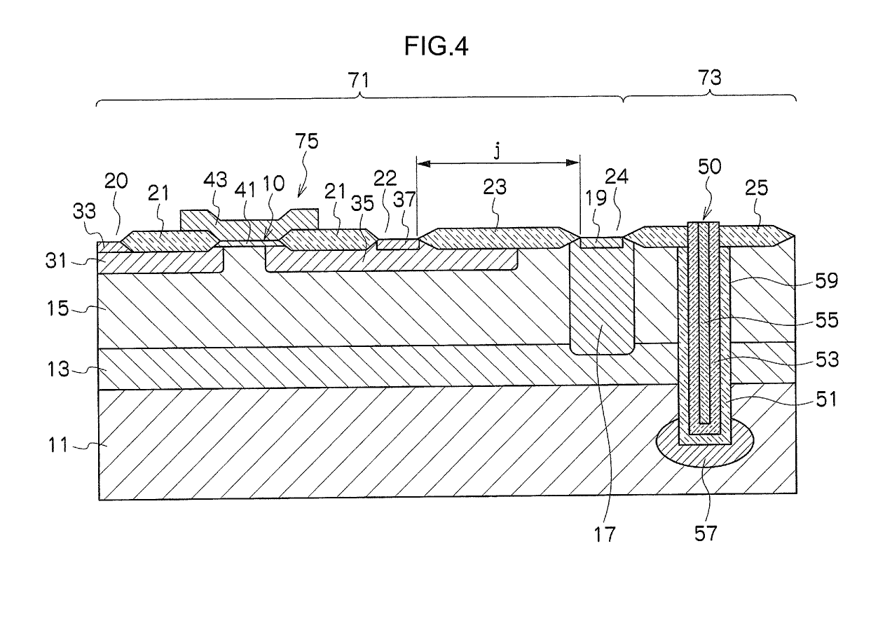

In the conventional structure as shown in FIG. 4, the distance “j” between the p⁺-type drain contact area 37 of the drain region 35 and the n⁺-type contact area 19 of the sinker 17 is, for example, 6 μm. However, in the present embodiment, by providing the isolation trench 60 between the p⁻ drain region 35 of the high withstand voltage p-type MOS transistor 75 and the n-type sinker 17, the distance “i” between the p⁺-type drain contact area 37 of the drain region 35 and the N⁺-type contact area 19 of the sinker 17 can be reduced to, for example, 1.4 μm (0.4 μm (the opening width “e” of the trench 67) +0.5 μm (the width “g” of the field oxide film 23 at the side of the p⁻ drain region 35) +0.5 μm (the width “h” of the field oxide film 23 at the side of the n-type sinker 17)=1.4 μm). As a result, the element region can be reduced by about 40% at the maximum without using an additional process and an additional mask. Further, the trench 59 for element isolation and the trench 67 for the insulation trench 60 formed between the drain region 35 and the sinker 17 can be formed at the same time by adjusting the respective opening widths “c”, “e” of the both trenches, and the number of manufacturing processes is reduced compared to a case in which the trenches are formed separately. Moreover, an insulator to be formed in the trench 59 and an insulator to be formed in the trench 67 can also be formed at the same time, which leads to reduction in the number of manufacturing processes.

What is claimed is:

1. A semiconductor device comprising:
a first semiconductor layer of one conductivity type provided on a substrate;
a second semiconductor layer of the one conductivity type provided on the first semiconductor layer, the second semiconductor layer having a lower impurity concentration than the first semiconductor layer;
an isolation region that extends from one principal face of the second semiconductor layer to reach the substrate, the one principal face being located at a side opposite to the first semiconductor layer;
a first region provided in an element region of the second semiconductor layer isolated by the isolation region, the first region having an opposite conductivity type to the one conductivity type;
a second region of the one conductivity type provided in the element region, the second region extending from the one principal face to reach the first semiconductor layer, and having an impurity concentration higher than that of the second semiconductor layer; and
an insulation region provided between the first region and the second region, the insulation region extending from the one principal face of the second semiconductor layer to the first semiconductor layer and being kept away from the substrate.

2. The semiconductor device according to claim 1, wherein an end portion of the insulation region at a side opposite to the one principal face is located in the first semiconductor layer.

3. The semiconductor device according to claim 1, wherein an end portion of the insulation region at a side opposite to the one principal face contacts a face of the first semiconductor layer at a side of the second semiconductor layer.

4. The semiconductor device according to claim 1, wherein the substrate is a semiconductor substrate of the opposite conductivity type.

5. The semiconductor device according to claim 1, wherein the insulation region includes: a first trench extending from the one principal face of the second semiconductor layer to reach the first semiconductor layer; and a first insulator provided in the first trench.

6. The semiconductor device according to claim 5, wherein the isolation region includes: a second trench extending from the one principal face of the second semiconductor layer to reach the substrate; and a second insulator provided in the second trench.

7. The semiconductor device according to claim 6, wherein a width of an opening of the second trench at a side of the one principal face is larger than a width of an opening of the first trench at the side of the one principal face.

8. The semiconductor device according to claim 1, wherein the element region has an insulated gate type transistor, and the first region is a drain region of the insulated gate type transistor.

9. A manufacturing method of a semiconductor device, comprising:
preparing a semiconductor substrate that has a substrate, a first semiconductor layer of one conductivity type that is provided on the substrate, and a second semiconductor layer of the one conductivity type that is provided on the first semiconductor layer, the first semiconductor layer having an impurity concentration higher than that of the second semiconductor layer;
forming a first region by implanting first impurities of an opposite conductivity type to the one conductivity type into a surface of the semiconductor substrate from a side of the second semiconductor layer;
forming a second region extending from the surface of the semiconductor substrate to reach the first semiconductor layer by implanting second impurities of the one conductivity type into the surface from the side of the second semiconductor layer, the second region having an impurity concentration higher than that of the second semiconductor layer;
forming a first trench that surrounds the first region and the second region, and extends from the surface of the semiconductor substrate to reach the substrate;
forming a second trench between the first region and the second region, the second trench extending from the surface of the semiconductor substrate to reach the first semiconductor layer;
forming a first insulator in the first trench; and
forming a second insulator in the second trench.

10. The manufacturing method of a semiconductor device according to claim 9, wherein a width of an opening of the second trench at a side of the surface of the semiconductor substrate is larger than a width of an opening of the first trench at the side of the surface of the semiconductor substrate, and the first trench and the second trench are formed in the same process by etching.

11. The manufacturing method of a semiconductor device according to claim 9 wherein the first insulator and the second insulator are formed in the same process.

12. The manufacturing method of a semiconductor device according to claim 9, wherein the second trench is formed so as to reach an inside of the first semiconductor layer.

13. The manufacturing method of a semiconductor device according to claim 9, wherein the insulation region is formed so that an end portion of the insulation region contacts a surface of the first semiconductor layer at a side of the second semiconductor layer.

14. The manufacturing method of a semiconductor device claim 9, wherein the substrate is of the opposite conductivity type.

15. The manufacturing method of a semiconductor device according to claim 9, wherein the first region is a drain of an insulated gate type transistor.
